(19) United States
(12) Patent Application Publication
(10) Pub. No.: US 2026/0026028 A1
(43) Pub. Date: Jan. 22, 2026

(54) NITRIDE SEMICONDUCTOR DEVICE, AND PRODUCTION METHOD OF NITRIDE SEMICONDUCTOR DEVICE

(71) Applicant: SUMITOMO ELECTRIC INDUSTRIES, LTD., Osaka (JP)

(72) Inventor: Takahide HIRASAKI, Osaka (JP)

(21) Appl. No.: 19/262,656

(22) Filed: Jul. 8, 2025

(30) Foreign Application Priority Data
Jul. 19, 2024 (JP) 2024-115913

(51) Int. Cl. H10D 30/47; H10D 30/01; H10D 62/85

(52) U.S. Cl. CPC H10D 30/475; H10D 30/015; H10D 62/8503

(57) ABSTRACT

A nitride semiconductor device includes a first nitride semiconductor layer including a channel layer and a barrier layer overlaid along a first axis, the first nitride semiconductor layer including a first surface perpendicular to the first axis; and a second nitride semiconductor layer and a third nitride semiconductor layer sandwiching the channel layer and the barrier layer between the second nitride semiconductor layer and the third nitride semiconductor layer along a second axis perpendicular to the first axis. In a cross-sectional view including the first axis and the second axis, the second nitride semiconductor layer includes a first covering portion covering a first portion of the first surface, and the third nitride semiconductor layer includes a second covering portion covering a second portion of the first surface.

### CROSS-REFERENCE TO RELATED APPLICATIONS

This application is based on and claims priority to Japanese Patent Application No. 2024-115913, filed on Jul. 19, 2024, the entire contents of which are incorporated herein by reference.

### TECHNICAL FIELD

The present disclosure relates to a nitride semiconductor device, and a production method of the nitride semiconductor device.

### BACKGROUND

For reducing the contact resistance and the like in nitride semiconductor devices, a structure in which a nitride semiconductor layer containing impurities at a high concentration is regrown has been proposed. See, for example, Unexamined Japanese Patent Application Publication No. 2007-329350, and PCT Japanese Translation Patent Publication No. 2007-538402.

### SUMMARY

A nitride semiconductor device of the present disclosure includes: a first nitride semiconductor layer including a channel layer and a barrier layer stacked along a first axis, the first nitride semiconductor layer including a first surface perpendicular to the first axis; and a second nitride semiconductor layer and a third nitride semiconductor layer sandwiching the channel layer and the barrier layer between the second nitride semiconductor layer and the third nitride semiconductor layer along a second axis perpendicular to the first axis. In a cross-sectional view including the first axis and the second axis, the second nitride semiconductor layer includes a first covering portion covering a first portion of the first surface, and the third nitride semiconductor layer includes a second covering portion covering a second portion of the first surface.

### BRIEF DESCRIPTION OF THE DRAWINGS

FIG. 1 is a cross-sectional view illustrating a nitride semiconductor device according to an embodiment of the present disclosure.

FIG. 2 is a plan view illustrating the nitride semiconductor device according to the embodiment.

FIG. 3 is a cross-sectional view illustrating a first production method of the nitride semiconductor device according to the embodiment (part 1).

FIG. 4 is a cross-sectional view illustrating the first production method of the nitride semiconductor device according to the embodiment (part 2).

FIG. 5 is a cross-sectional view illustrating the first production method of the nitride semiconductor device according to the embodiment (part 3).

FIG. 6 is a cross-sectional view illustrating the first production method of the nitride semiconductor device according to the embodiment (part 4).

FIG. 7 is a cross-sectional view illustrating the first production method of the nitride semiconductor device according to the embodiment (part 5).

FIG. 8 is a cross-sectional view illustrating the first production method of the nitride semiconductor device according to the embodiment (part 6).

FIG. 9 is a cross-sectional view illustrating the first production method of the nitride semiconductor device according to the embodiment (part 7).

FIG. 10 is a cross-sectional view illustrating a second production method of the nitride semiconductor device according to the embodiment (part 1).

FIG. 11 is a cross-sectional view illustrating the second production method of the nitride semiconductor device according to the embodiment (part 2).

FIG. 12 is a cross-sectional view illustrating the second production method of the nitride semiconductor device according to the embodiment (part 3).

FIG. 13 is a cross-sectional view illustrating the second production method of the nitride semiconductor device according to the embodiment (part 4).

FIG. 14 is a cross-sectional view illustrating the second production method of the nitride semiconductor device according to the embodiment (part 5).

FIG. 15 is a cross-sectional view illustrating a phenomenon in the nitride semiconductor device according to the embodiment.

FIG. 16 is a cross-sectional view illustrating a phenomenon in a nitride semiconductor device according to a Reference Example.

### DETAILED DESCRIPTION

In recent years, there has been a growing need for further improvement in breakdown voltage.

The present disclosure provides a nitride semiconductor device having a high breakdown voltage, and a production method of the nitride semiconductor device.

### DESCRIPTION OF EMBODIMENTS OF PRESENT DISCLOSURE

First, embodiments of the present disclosure will be listed and described.

[1] A nitride semiconductor device according to an aspect of the present disclosure includes: a first nitride semiconductor layer including a channel layer and a barrier layer stacked along a first axis, the first nitride semiconductor layer including a first surface perpendicular to the first axis; and a second nitride semiconductor layer and a third nitride semiconductor layer sandwiching the channel layer and the barrier layer between the second nitride semiconductor layer and the third nitride semiconductor layer along a second axis perpendicular to the first axis. In a cross-sectional view including the first axis and the second axis, the second nitride semiconductor layer includes a first covering portion covering a first portion of the first surface, and the third nitride semiconductor layer includes a second covering portion covering a second portion of the first surface.

When the second nitride semiconductor layer and the third nitride semiconductor layer are formed through sputtering, there may be a case in which dents are formed unevenly in the top surface of the second nitride semiconductor layer and the top surface of the third nitride semiconductor layer. Also, a polycrystalline layer may be formed at unwanted portions. Because the second nitride semiconductor layer includes the first covering portion and the third nitride semiconductor layer includes the second covering portion, dents are substantially formed in the first covering portion and the second covering portion. Therefore, even if low-crystallinity portions of the second nitride semiconductor layer and the third nitride semiconductor layer are slightly etched in the vicinity of the dents upon removal of the polycrystalline layer, the barrier layer and the channel layer are not etched, and a high breakdown voltage can be achieved in the nitride semiconductor device.

[2] In [1], the first nitride semiconductor layer may include a second surface opposite to the first surface. The second nitride semiconductor layer may include a third surface having a distance from the second surface, the distance being greater than a first distance between the first surface and the second surface. The third nitride semiconductor layer may include a fourth surface having a distance from the second surface, the distance being greater than the first distance. In this case, etching of the barrier layer and the channel layer can be readily prevented.

[3] In [2], a distance between the first surface and the third surface may be 5 nm or more and 30 nm or less, and a distance between the first surface and the fourth surface may be 5 nm or more and 30 nm or less. When these distances are 5 nm or more, etching of the barrier layer and the channel layer can be more readily prevented. When these distances are 30 nm or less, formation of any excessive steps can be readily prevented.

[4] In any one of [1] to [3], the first nitride semiconductor layer may include a cap layer including the first surface. In this case, a gate leakage current can be reduced, and long-term reliability can be improved.

[5] In any one of [1] to [4], a length of the first covering portion in a direction along the second axis may be 30 nm or more and 200 nm or less, and a length of the second covering portion in the direction along the second axis may be 30 nm or more and 200 nm or less. When these lengths are 30 nm or more, etching of the barrier layer and the channel layer can be more readily prevented. When these lengths are 200 nm or less, short circuits between a gate electrode, provided between the second nitride semiconductor layer and the third nitride semiconductor layer, and the second nitride semiconductor layer and the third nitride semiconductor layer can be readily prevented.

[6] In any one of [1] to [5], the channel layer may include a channel region containing a two dimensional electron gas, and an electrical resistance of the second nitride semiconductor layer and an electrical resistance of the third nitride semiconductor layer may be lower than an electrical resistance of the channel region. In this case, it is possible to lower an electrical resistance between electrodes provided over the second nitride semiconductor layer and the third nitride semiconductor layer.

[7] In any one of [1] to [6], the second nitride semiconductor layer and the third nitride semiconductor layer may contain n-type impurities. In this case, a low electrical resistance can be readily achieved in the second nitride semiconductor layer and the third nitride semiconductor layer.

[8] In [7], a concentration of the n-type impurities may be 1×10²⁰ cm⁻³ or more. In this case, an especially low electrical resistance can be readily achieved in the second nitride semiconductor layer and the third nitride semiconductor layer.

[9] In any one of [1] to [8], the first nitride semiconductor layer may include a first recess and a second recess sandwiching the channel layer and the barrier layer between the first recess and the second recess along the second axis. The second nitride semiconductor layer may be provided in the first recess, and the third nitride semiconductor layer may be provided in the second recess. In this case, the second nitride semiconductor layer and the third nitride semiconductor layer can be readily formed.

[10] In any one of [1] to [9], the nitride semiconductor device may include an insulating layer provided over the first surface and in contact with the first covering portion and the second covering portion. In this case, the first nitride semiconductor layer can be protected by the insulating layer.

[11] A production method of a nitride semiconductor device according to another aspect of the present disclosure includes: providing a first nitride semiconductor layer including a channel layer and a barrier layer stacked along a first axis, the first nitride semiconductor layer including a first surface perpendicular to the first axis; and forming a second nitride semiconductor layer and a third nitride semiconductor layer through sputtering, the second nitride semiconductor layer and the third nitride semiconductor sandwiching the channel layer and the barrier layer between the second nitride semiconductor layer and the third nitride semiconductor layer along a second axis perpendicular to the first axis. In a cross-sectional view including the first axis and the second axis, the second nitride semiconductor layer includes a first covering portion covering a first portion of the first surface, and the third nitride semiconductor layer includes a second covering portion covering a second portion of the first surface.

As described above, even if low-crystallinity portions of the second nitride semiconductor layer and the third nitride semiconductor layer are slightly etched in the vicinity of the dents upon removal of the polycrystalline layer, the barrier layer and the channel layer are not etched, and a high breakdown voltage can be achieved in the nitride semiconductor device.

[12] In [11], the production method of the nitride semiconductor device may include, between the provision of the first nitride semiconductor layer and the formation of both the second nitride semiconductor layer and the third nitride semiconductor layer, forming a first recess and a second recess in the first nitride semiconductor layer, the first recess and the second recess sandwiching the channel layer and the barrier layer between the first recess and the second recess along the second axis. The second nitride semiconductor layer may be formed in the first recess, and the third nitride semiconductor layer may be formed in the second recess. In this case, the second nitride semiconductor layer and the third nitride semiconductor layer can be readily formed.

[13] In [12], the production method of the nitride semiconductor device may include, between the provision of the first nitride semiconductor layer and the formation of both the first recess and the second recess, forming an insulating layer over the first surface; forming a mask over the insulating layer, the mask including a first opening and a second opening; and etching the insulating layer through the first opening and the second opening to form a third opening and a fourth opening in the insulating layer, the third opening being continuous with the first opening and larger than the first opening in a plan view and the fourth opening being continuous with the second opening and larger than the second opening in the plan view. The first recess and the second recess may be formed by etching through the first opening and the second opening. The production method of the nitride semiconductor device may include removing the mask between the formation of both the first recess and the second recess and the formation of both the second nitride semiconductor layer and the third nitride semiconductor layer. In this case, the sizes of the first covering portion and the second covering portion can be adjusted upon etching of the insulating layer.

[14] In [12], the production method of the nitride semiconductor device may include, between the provision of the first nitride semiconductor layer and the formation of both the first recess and the second recess, forming an insulating layer over the first surface; forming a mask over the insulating layer, the mask including a first opening and a second opening; and etching the insulating layer through the first opening and the second opening to form a fifth opening and a sixth opening in the insulating layer, the fifth opening being continuous with the first opening and the sixth opening being continuous with the second opening. The first recess and the second recess may be formed by etching through the first opening and the second opening. The production method of the nitride semiconductor device may include, between the formation of both the first recess and the second recess and the formation of both the second nitride semiconductor layer and the third nitride semiconductor layer, ashing the mask to widen the first opening and the second opening and expose a first portion of the insulating layer from the first opening and a second portion of the insulating layer from the second opening; removing the first portion of the insulating layer exposed from the first opening and the second portion of the insulating layer exposed from the second opening; and removing the mask after the removal of the first portion of the insulating layer exposed from the first opening and the second portion of the insulating layer exposed from the second opening. In this case, the sizes of the first covering portion and the second covering portion can be adjusted upon ashing of the mask.

### Details of Embodiments of Present Disclosure

Hereinafter, embodiments of the present disclosure will be described in detail, but the present disclosure is not limited thereto. In the present specification and drawings, components having substantially the same functional configuration are denoted by the same reference symbols, and duplicate description thereof may be omitted. In the following description, an XYZ orthogonal coordinate system is used. However, this coordinate system is provided for the description, and does not limit the orientation of the nitride semiconductor device. Also, an XY plan view is referred to as a plan view, and when viewed from a given point, a +Z direction may be referred to as upward, upper side, above, or top, and a −Z direction may be referred to as downward, lower side, below, or bottom.

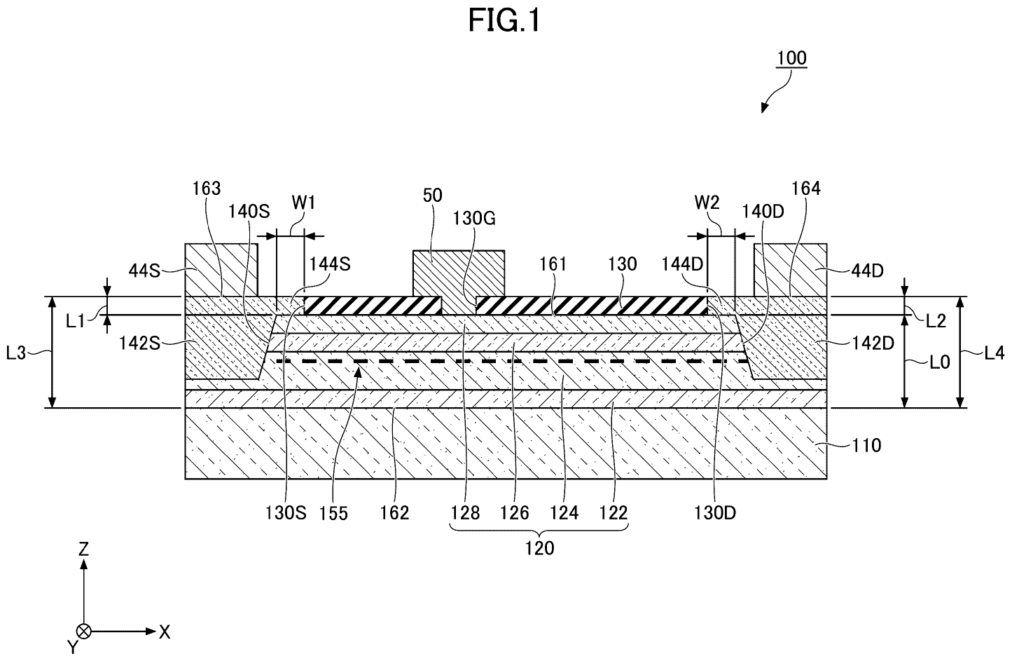

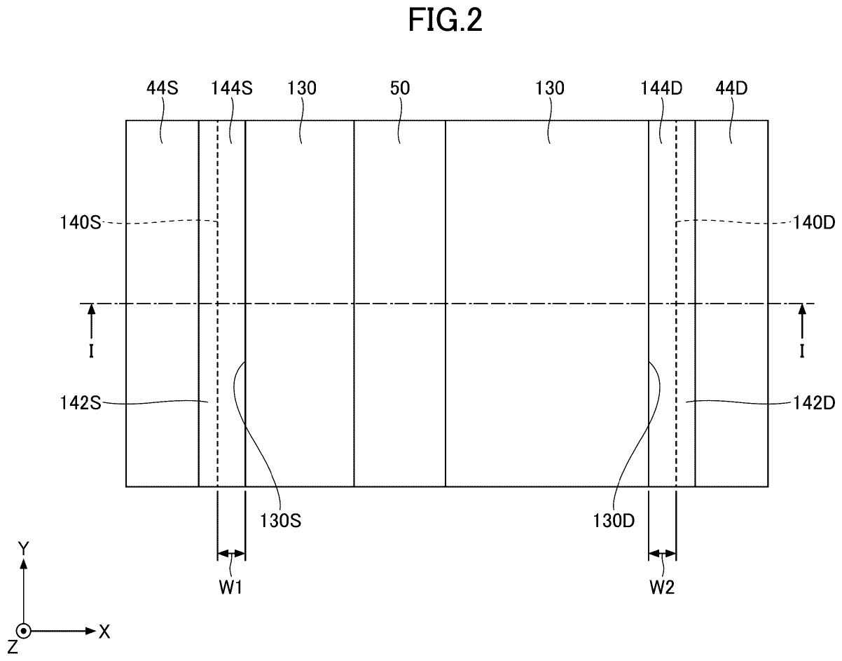

An embodiment of the present disclosure relates to a nitride semiconductor device including a high electron mobility transistor (HEMT). FIG. 1 is a cross-sectional view illustrating the nitride semiconductor device according to the embodiment. FIG. 2 is a plan view illustrating the nitride semiconductor device according to the embodiment. FIG. 1 corresponds to a cross-sectional view taken along the line I-I in FIG. 2.

As illustrated in FIGS. 1 and 2, a nitride semiconductor device 100 according to the embodiment includes a substrate 110, a first nitride semiconductor layer 120, a second nitride semiconductor layer 142S, a third nitride semiconductor layer 142D, an insulating layer 130, a gate electrode 50, a source electrode 44S, and a drain electrode 44D.

The substrate 110 is, for example, a substrate for growth of a gallium nitride (GaN)-based semiconductor layer, and is, for example, a semi-insulating silicon carbide (SiC) substrate. When the substrate 110 is a SiC substrate, the top surface of the substrate 110 is a surface of silicon (Si) polarity. When the surface of the substrate 110 is a surface of Si polarity, crystal growth of the first nitride semiconductor layer 120 is performed from a surface of gallium (Ga) polarity serving as the surface for growth.

The first nitride semiconductor layer 120 includes a buffer layer 122, a channel layer 124, a barrier layer 126, and a cap layer 128. The buffer layer 122, the channel layer 124, the barrier layer 126, and the cap layer 128 are stacked in this order along a Z axis. The first nitride semiconductor layer 120 includes a top surface 161 and a bottom surface 162 that are perpendicular to the Z axis. The cap layer 128 includes the top surface 161. The Z axis is an example of a first axis. The top surface 161 is an example of a first surface, and the bottom surface 162 is an example of a second surface opposite to the first surface.

The buffer layer 122 is over the substrate 110. The buffer layer 122 is, for example, an aluminum nitride (AlN) layer. The buffer layer 122 may include an AlN layer, and a GaN layer or an aluminum gallium nitride (AlGaN) layer over the AlN layer. The channel layer 124 is over the buffer layer 122. The channel layer 124 is, for example, an undoped gallium nitride (GaN) layer. The barrier layer 126 is over the channel layer 124. The barrier layer 126 is, for example, an n-type AlGaN layer. A channel region 155 containing a two dimensional electron gas (2DEG) is in the vicinity of the top surface of the channel layer 124. The cap layer 128 is over the barrier layer 126. The cap layer 128 is, for example, an n-type GaN layer.

A first recess 140S for a source and a second recess 140D for a drain are formed in the cap layer 128, the barrier layer 126, and a portion of the channel layer 124. The first recess 140S and the second recess 140D penetrate through the cap layer 128 and the barrier layer 126, and enter the channel layer 124. The channel layer 124 is exposed from the first recess 140S and the second recess 140D.

The insulating layer 130 is over the cap layer 128. The insulating layer 130 is, for example, a silicon nitride (SiN) film. The thickness of the insulating layer 130 is, for example, 1 nm or more and 10 nm or less. An opening 130S for a source and an opening 130D for a drain are formed in the insulating layer 130. The opening 130S is continuous with the first recess 140S, and the opening 130D is continuous with the second recess 140D. The opening 130D is on a +X side of the opening 130S. In the plan view, the opening 130S is larger than the first recess 140S, and the opening 130D is larger than the second recess 140D. In an X-axis direction, a +X-side edge of the opening 130S is on a +X side relative to a +X-side edge of the first recess 140S, and a −X-side edge of the opening 130D is on a −X side relative to a −X-side edge of the second recess 140D. An X axis is an example of a second axis.

The second nitride semiconductor layer 142S is over the cap layer 128 and the channel layer 124 in the first recess 140S and the opening 130S. In a ZX cross-sectional view including the Z axis and the X axis, the second nitride semiconductor layer 142S includes a first covering portion 144S covering a portion of the top surface 161. The second nitride semiconductor layer 142S includes a top surface 163. A distance L3 of the top surface 163 from the bottom surface 162 of the first nitride semiconductor layer 120 may be greater than a first distance L0 between the top surface 161 and the bottom surface 162 of the first nitride semiconductor layer 120. The second nitride semiconductor layer 142S contacts a side wall of the opening 130S and a side wall of the first recess 140S. The top surface 163 is an example of a third surface.

The third nitride semiconductor layer 142D is over the cap layer 128 and the channel layer 124 in the second recess 140D and the opening 130D. In the ZX cross-sectional view including the Z axis and the X axis, the third nitride semiconductor layer 142D includes a second covering portion 144D covering a portion of the top surface 161. The third nitride semiconductor layer 142D includes a top surface 164. A distance L4 of the top surface 164 from the bottom surface 162 of the first nitride semiconductor layer 120 may be greater than the first distance L0 between the top surface 161 and the bottom surface 162 of the first nitride semiconductor layer 120. The third nitride semiconductor layer 142D contacts a side wall of the opening 130D and a side wall of the second recess 140D. The top surface 164 is an example of a fourth surface.

The second nitride semiconductor layer 142S and the third nitride semiconductor layer 142D sandwich the channel layer 124 and the barrier layer 126 between the second nitride semiconductor layer 142S and the third nitride semiconductor layer 142D along the X-axis. The second nitride semiconductor layer 142S and the third nitride semiconductor layer 142D are, for example, an n-type GaN layer. An electrical resistance of the second nitride semiconductor layer 142S and the third nitride semiconductor layer 142D is lower than an electrical resistance of the channel region 155.

The source electrode 44S is over the second nitride semiconductor layer 142S, and the drain electrode 44D is over the third nitride semiconductor layer 142D. The source electrode 44S is in direct contact with the second nitride semiconductor layer 142S, and the drain electrode 44D is in direct contact with the third nitride semiconductor layer 142D. The source electrode 44S is in Ohmic contact with the second nitride semiconductor layer 142S, and the drain electrode 44D is in Ohmic contact with the third nitride semiconductor layer 142D.

An opening 130G for a gate is formed in the insulating layer 130. The opening 130G is between the opening 130S and the opening 130D. The gate electrode 50 is provided over the insulating layer 130, and is in Schottky contact with the first nitride semiconductor layer 120 through the opening 130G.

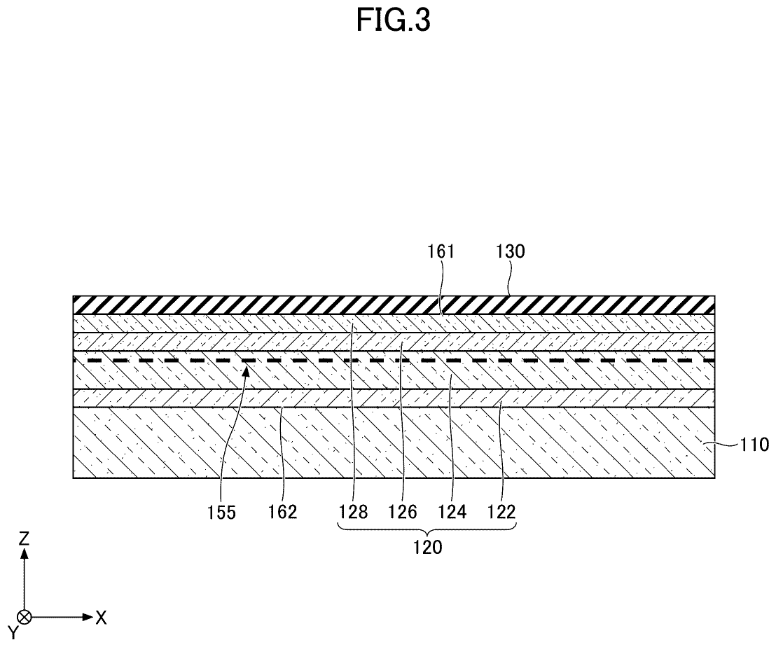

Next, a first production method of the nitride semiconductor device 100 according to the embodiment will be described. FIGS. 3 to 9 are cross-sectional views illustrating the first production method of the nitride semiconductor device 100 according to the embodiment.

In the first production method, as illustrated in FIG. 3, first, the buffer layer 122, the channel layer 124, the barrier layer 126, and the cap layer 128 are formed over the substrate 110. The buffer layer 122, the channel layer 124, the barrier layer 126, and the cap layer 128 can be formed, for example, through metal organic chemical vapor deposition (MOCVD). Next, the insulating layer 130 is formed over the cap layer 128. The insulating layer 130 can be formed, for example, through CVD. In this manner, the first nitride semiconductor layer 120 is obtained.

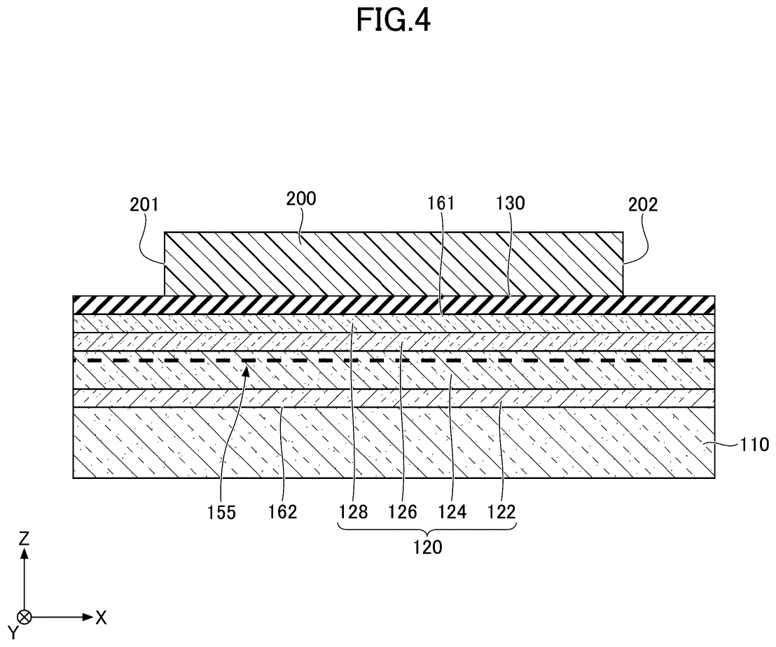

Next, as illustrated in FIG. 4, a mask 200 is formed over the insulating layer 130. The mask 200 includes an opening 201 for the first recess 140S and an opening 202 for the second recess 140D. For example, the mask 200 is formed of a photoresist. The opening 201 is an example of a first opening, and the opening 202 is an example of a second opening.

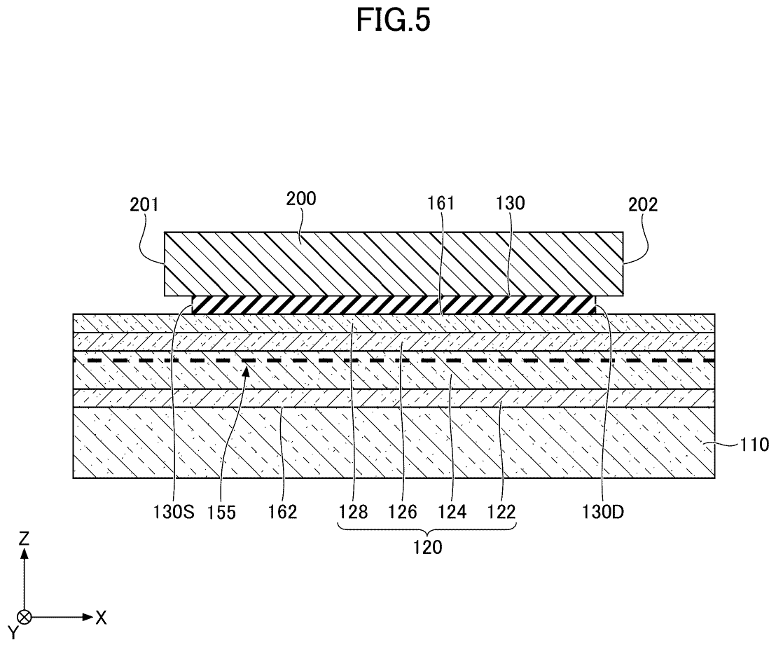

Next, as illustrated in FIG. 5, the insulating layer 130 is etched through the opening 201 and the opening 202 to form, in the insulating layer 130, the opening 130S continuous with the opening 201 and the opening 130D continuous with the opening 202. The etching of the insulating layer 130 is performed under conditions that side etching occurs, and in the plan view, the opening 130S is formed to be larger than the opening 201 and the opening 130D is formed to be larger than the opening 202. In the X-axis direction, the +X-side edge of the opening 130S is on the +X side relative to the +X-side edge of the opening 201, and the −X-side edge of the opening 130D is on the −X side relative to the −X-side edge of the opening 202. The opening 130S and the opening 130D can be formed, for example, through reactive ion etching (RIE) using a reactive gas containing fluorine (F). In the RIE, for example, an internal pressure of a chamber is set to be 2 Pa or more and 10 Pa or less, and a bias power is set to be 0 W or more and 2 W or less. The opening 130S is an example of a third opening, and the opening 130D is an example of a fourth opening.

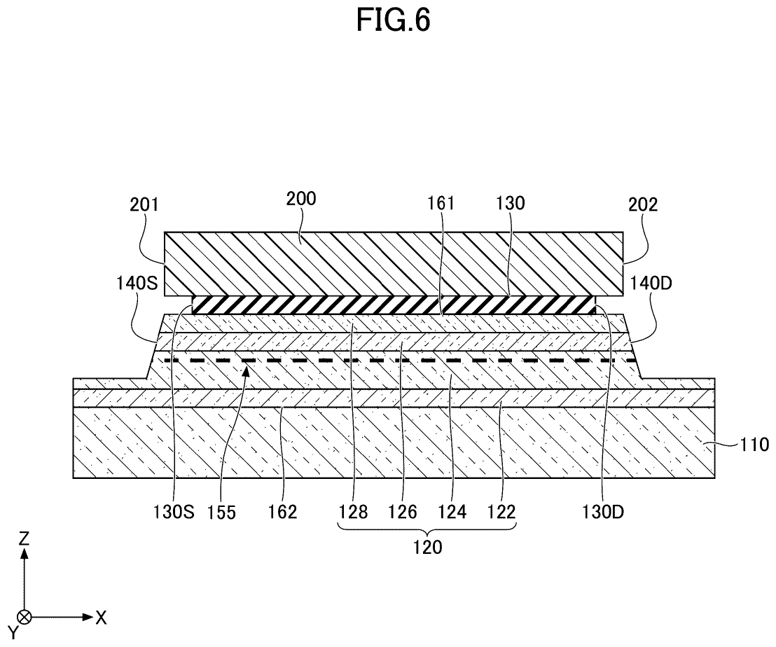

Next, as illustrated in FIG. 6, the first nitride semiconductor layer 120 is etched through the opening 201 and the opening 202 to form, in the first nitride semiconductor layer 120, the first recess 140S continuous with the opening 130S and the second recess 140D continuous with the opening 130D. The first recess 140S and the second recess 140D sandwich the channel layer 124 and the barrier layer 126 between the first recess 140S and the second recess 140D along the X axis. The first recess 140S and the second recess 140D can be formed, for example, through RIE using a reactive gas containing chlorine (Cl). In the RIE, for example, an internal pressure of a chamber is set to be 0.2 Pa or more and 5 Pa or less, and a bias power is set to be 1 W or more and 5 W or less. For example, angles formed between the side walls of the first recess 140S and the second recess 140D, and the top surface 161 of the first nitride semiconductor layer 120 are set to be closer to 90 degrees.

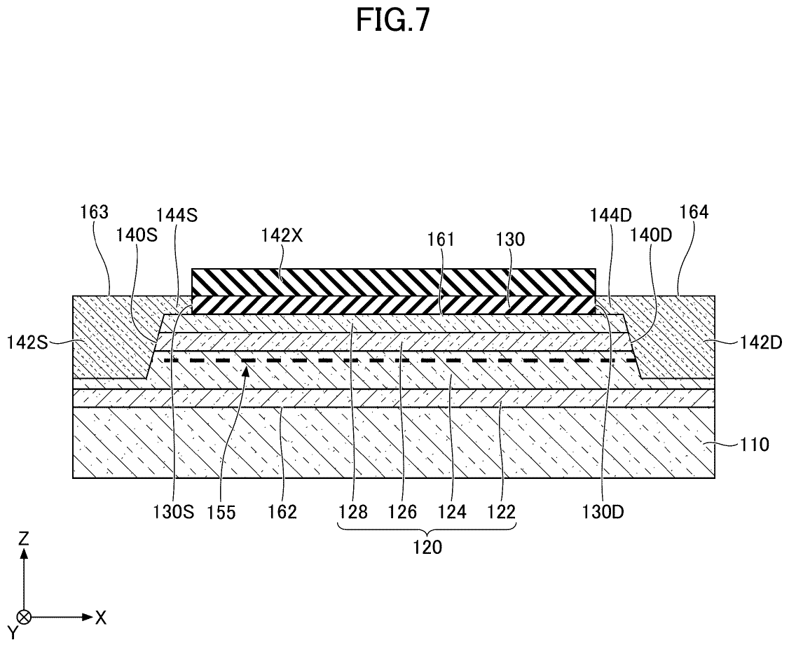

Next, as illustrated in FIG. 7, the mask 200 is removed. Next, the second nitride semiconductor layer 142S is formed in the first recess 140S and the opening 130S, and the third nitride semiconductor layer 142D is formed in the second recess 140D and the opening 130D. The second nitride semiconductor layer 142S is formed over the cap layer 128 and the channel layer 124 in the first recess 140S and the opening 130S. The third nitride semiconductor layer 142D is formed over the cap layer 128 and the channel layer 124 in the second recess 140D and the opening 130D. The −X-side end of the cap layer 128 is covered by the second nitride semiconductor layer 142S, and the +X-side end of the cap layer 128 is covered by the third nitride semiconductor layer 142D. The second nitride semiconductor layer 142S and the third nitride semiconductor layer 142D can be formed, for example, through sputtering. When the second nitride semiconductor layer 142S and the third nitride semiconductor layer 142D are formed through sputtering, supply of Ga and supply of n-type impurities may be intermittently performed while supply of nitrogen radicals is continued. The second nitride semiconductor layer 142S and the third nitride semiconductor layer 142D are single crystals and epitaxially grown. In addition, a polycrystalline layer 142X is also formed over the insulating layer 130.

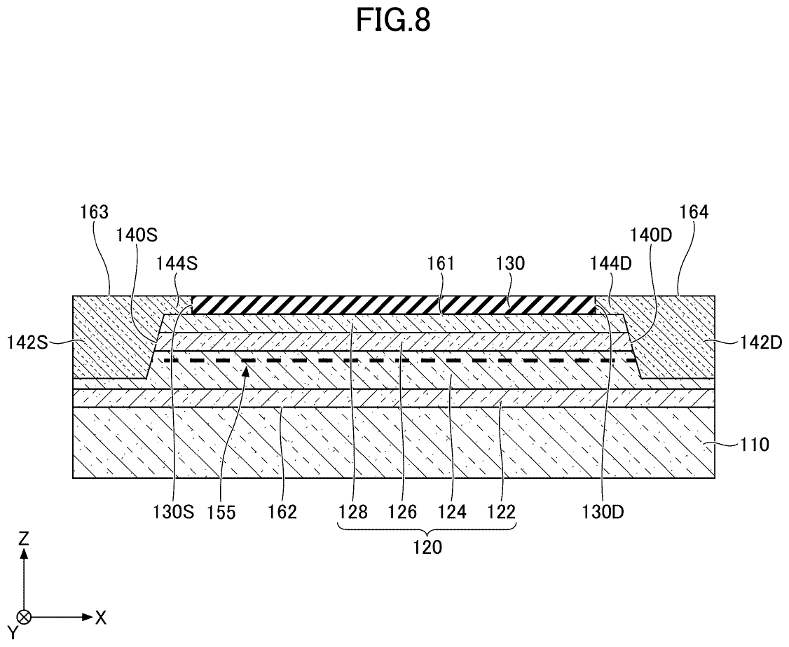

Next, as illustrated in FIG. 8, the polycrystalline layer 142X is removed. The polycrystalline layer 142X can be removed by use of an alkaline etchant, such as tetramethylammonium hydroxide (TMAH) or the like. At this time, the second nitride semiconductor layer 142S and the third nitride semiconductor layer 142D, which are single crystals, are hardly removed. This maintains a state in which the end of the cap layer 128 is covered by the second nitride semiconductor layer 142S and the third nitride semiconductor layer 142D. As a result, the etchant does not contact the first nitride semiconductor layer 120, and thus the first nitride semiconductor layer 120 is not etched.

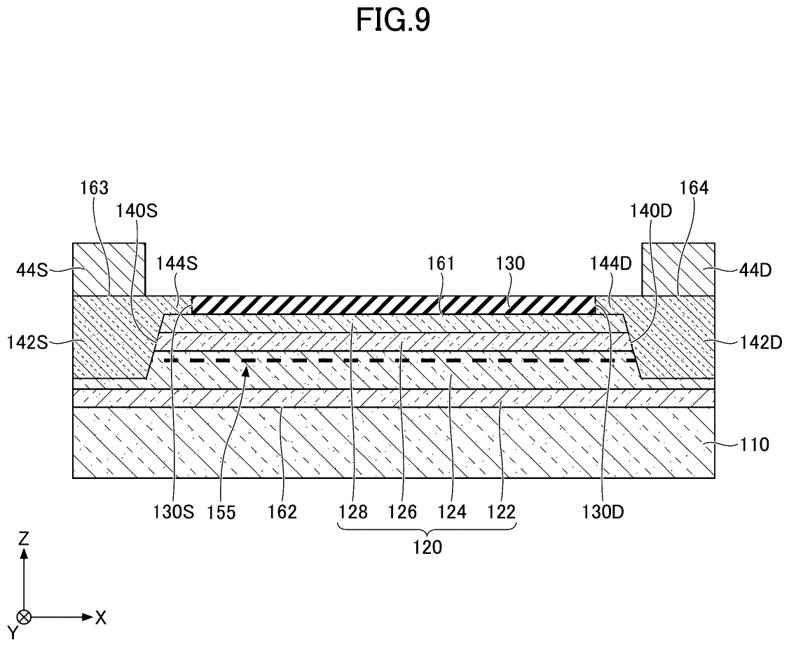

Next, as illustrated in FIG. 9, the source electrode 44S is formed over the second nitride semiconductor layer 142S, and the drain electrode 44D is formed over the third nitride semiconductor layer 142D. The source electrode 44S and the drain electrode 44D can be formed, for example, through vapor deposition and lift-off.

Next, the opening 130G is formed in the insulating layer 130. The opening 130G can be formed, for example, through RIE using a reactive gas containing fluorine (F). Next, the gate electrode 50 in Schottky contact with the first nitride semiconductor layer 120 through the opening 130G is formed over the insulating layer 130 (see FIG. 1).

In this manner, the nitride semiconductor device 100 according to the embodiment can be produced.

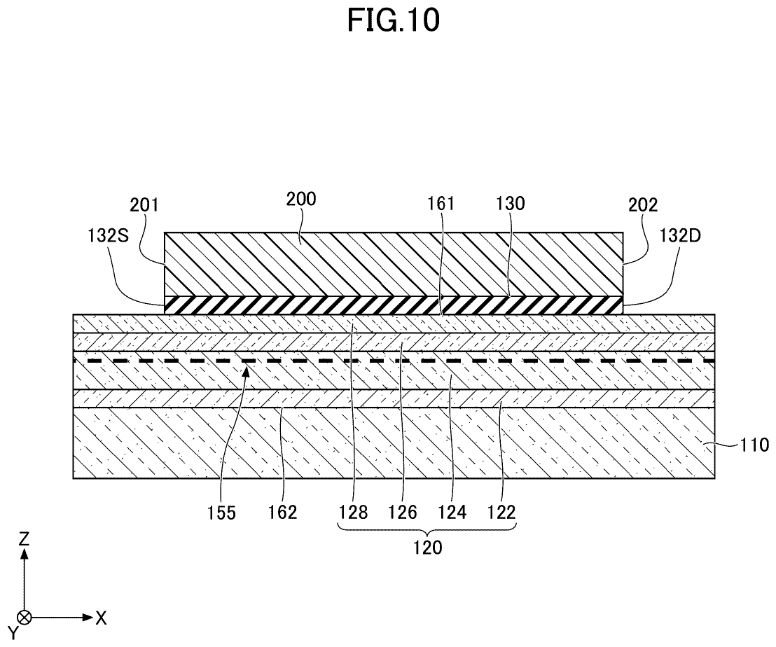

Next, a second production method of the nitride semiconductor device 100 according to the embodiment will be described. FIGS. 10 to 14 are cross-sectional views illustrating the second production method of the nitride semiconductor device 100 according to the embodiment.

In the second production method, first, a process up to the formation of the mask 200 is performed in the same manner as in the first production method (see FIG. 4). Next, as illustrated in FIG. 10, the insulating layer 130 is etched through the opening 201 and the opening 202 to form, in the insulating layer 130, an opening 132S continuous with the opening 201 and an opening 132D continuous with the opening 202. The insulating layer 130 is etched under conditions that side etching is unlikely to occur, and in the plan view, the opening 132S is formed to have the same size as the opening 201 and the opening 132D is formed to have the same size as the opening 202. For example, in the X-axis direction, the +X-side end of the opening 132S coincides with the +X-side end of the opening 201, and the −X-side end of the opening 132D coincides with the −X-side end of the opening 202. However, the above corresponding ends do not necessarily need to coincide with each other completely, and there may be manufacturing errors. The opening 132S and the opening 132D can be formed, for example, through RIE using a reactive gas containing fluorine (F). In the RIE, for example, an internal pressure of a chamber is set to be 0.5 Pa or more and 2 Pa or less, and a bias power is set to be 2 W or more and 5 W or less. The opening 132S is an example of a fifth opening, and the opening 132D is an example of a sixth opening.

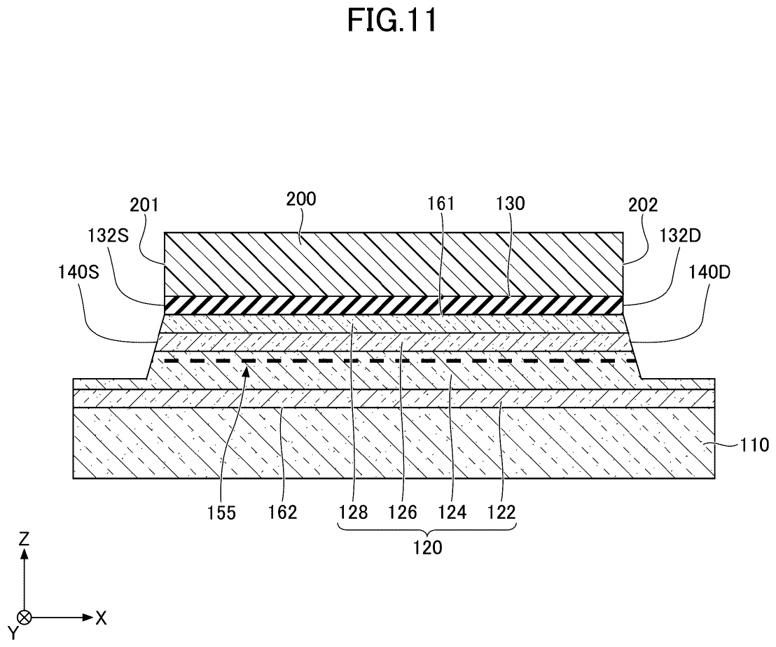

Next, as illustrated in FIG. 11, the first nitride semiconductor layer 120 is etched through the opening 201 and the opening 202 to form, in the first nitride semiconductor layer 120, the first recess 140S continuous with the opening 132S and the second recess 140D continuous with the opening 132D. The first recess 140S and the second recess 140D can be formed under the same conditions as in the first production method.

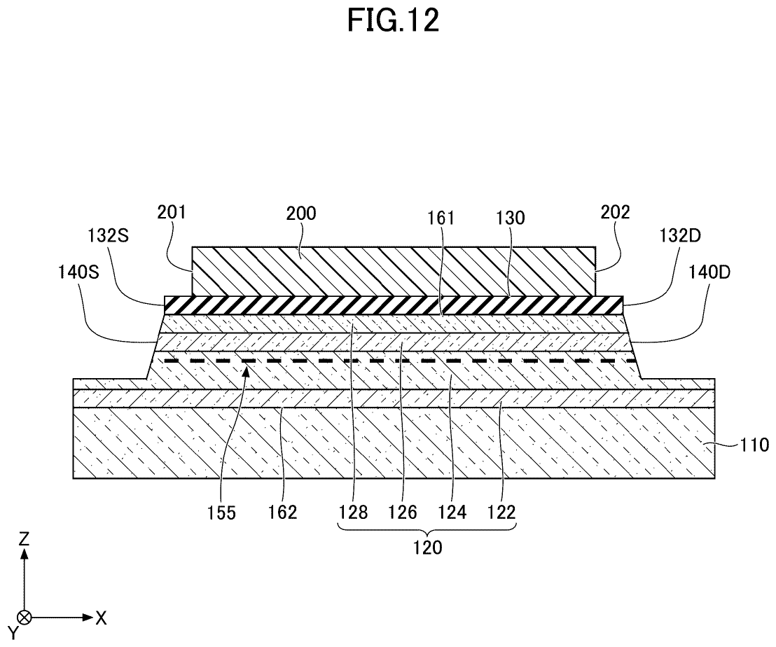

Next, as illustrated in FIG. 12, the mask 200 is ashed to widen the opening 201 and the opening 202, thereby exposing a first portion of the insulating layer 130 from the opening 201 and a second portion of the insulating layer 130 from the opening 202. In the ashing of the mask 200, the end of the mask 200 is removed, for example, using oxygen plasma. At this time, the upper portion of the mask 200 is also removed. However, by increasing the thickness of the mask 200 before ashing compared to the length by which the opening 201 and the opening 202 are to be widened, the mask 200 can be left after ashing to maintain the functions of the mask 200.

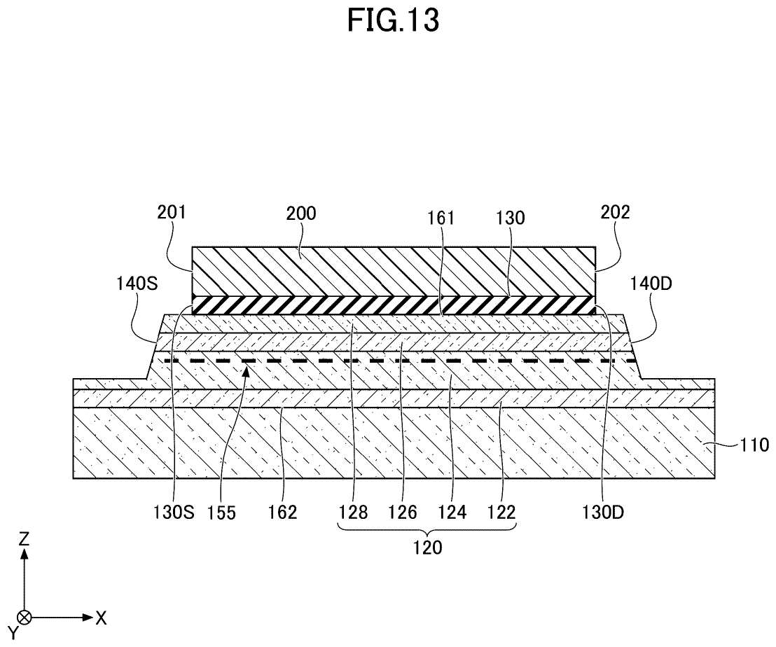

Next, as illustrated in FIG. 13, the portion of the insulating layer 130 exposed from the opening 201 and the portion of the insulating layer 130 exposed from the opening 202 are removed. The portion of the insulating layer 130 exposed from the opening 201 and the portion of the insulating layer 130 exposed from the opening 202 can be removed, for example, through RIE using a reactive gas containing fluorine (F). In the RIE, for example, an internal pressure of a chamber is set to be 0.5 Pa or more and 2 Pa or less, and a bias power is set to be 2 W or more and 5 W or less. As a result of this treatment, the opening 130S and the opening 130D are formed in the insulating layer 130.

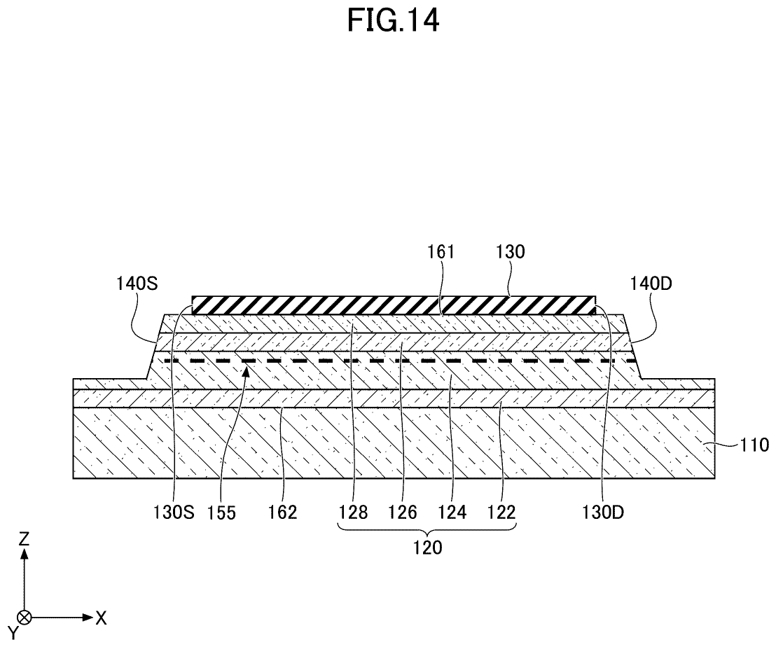

Next, as illustrated in FIG. 14, the mask 200 is removed. Subsequently, processes beginning with the formation of the second nitride semiconductor layer 142S and the third nitride semiconductor layer 142D are performed in the same manner as in the first production method.

In this manner, it is possible to produce the nitride semiconductor device 100 according to the embodiment.

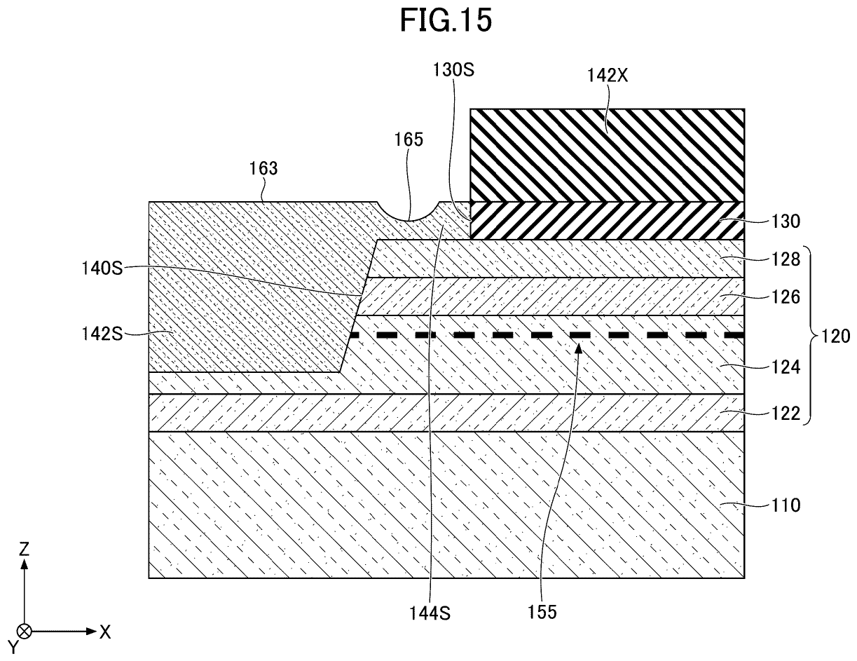

When the second nitride semiconductor layer 142S and the third nitride semiconductor layer 142D are formed through sputtering, as illustrated in FIG. 15, a dent 165 may be formed in the vicinity of the insulating layer 130 over the top surface of the second nitride semiconductor layer 142S or the third nitride semiconductor layer 142D. This is because a flow of raw materials flying from the target is partially blocked by the polycrystalline layer 142X that was already formed. Also, the shape and size of the dent 165 in the ZX cross-sectional view become uneven along a Y-axis direction. In the present embodiment, the second nitride semiconductor layer 142S includes the first covering portion 144S and the third nitride semiconductor layer 142D includes the second covering portion 144D, and the dent 165 is typically formed in the first covering portion 144S or the second covering portion 144D. Upon removal of the polycrystalline layer 142X, the second nitride semiconductor layer 142S and the third nitride semiconductor layer 142D are hardly etched, but a low-crystallinity portion in the vicinity of the dent 165 can be slightly etched. However, because the low-crystallinity portion in the vicinity of the dent 165 is in the first covering portion 144S or the second covering portion 144D, even if the first covering portion 144S or the second covering portion 144D is slightly etched, the cap layer 128, the barrier layer 126, and the channel layer 124 are not etched. Therefore, a high breakdown voltage can be achieved in the nitride semiconductor device 100.

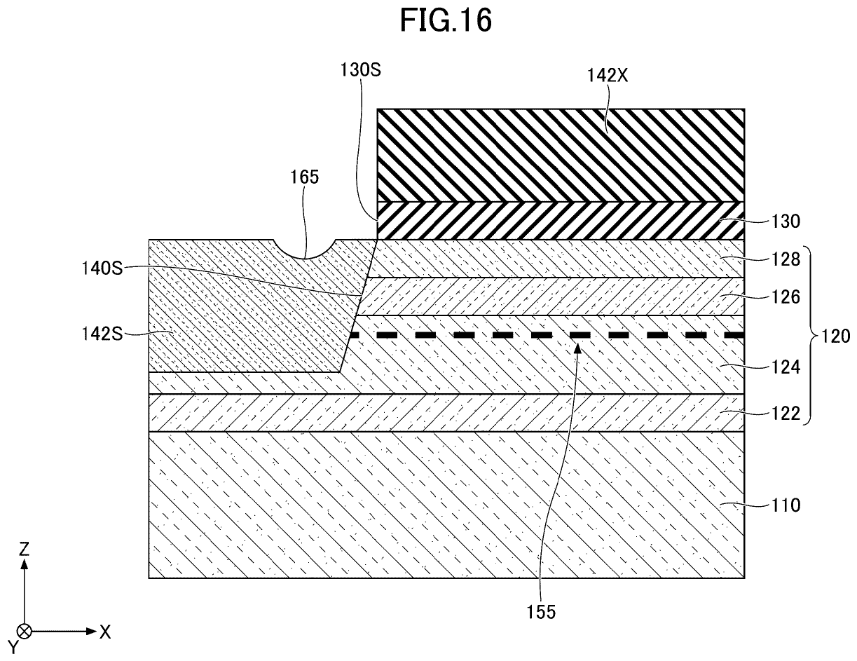

On the other hand, as in a nitride semiconductor device according to a Reference Example illustrated in FIG. 16, when a bottom end of the opening 130S and a top end of the first recess 140S overlap with each other in the plan view, a low-crystallinity portion included in the second nitride semiconductor layer 142S can be slightly etched upon removal of the polycrystalline layer 142X. When the low-crystallinity portion included in the second nitride semiconductor layer 142S is slightly etched, the cap layer 128 and the barrier layer 126 can be etched in accordance with the shape and size of the dent 165 in the ZX cross-sectional view. Similarly, when a low-crystallinity portion included in the third nitride semiconductor layer 142D is slightly etched, the cap layer 128 and the barrier layer 126 can be etched in accordance with the shape and size of the dent 165 in the ZX cross-sectional view. Also, an etching level of the barrier layer 126 becomes uneven along the Y-axis direction. Therefore, the 2DEG concentration becomes uneven along the Y-axis direction, and a current tends to concentrate in a portion where the 2DEG concentration is high and the electrical resistance is low. As a result, the breakdown voltage can be lowered.

When the distance L3 of the top surface 163 from the bottom surface 162 is greater than the first distance L0 between the top surface 161 and the bottom surface 162 of the first nitride semiconductor layer 120, etching of the barrier layer 126 and the channel layer 124 in the vicinity of the second nitride semiconductor layer 142S can be readily prevented. For example, the dent 165 forms above the cap layer 128 in a Z-axis direction, and thus etching of the dent 165 hardly affects the cap layer 128 and the barrier layer 126. When the distance L4 of the top surface 164 from the bottom surface 162 is greater than the first distance L0 between the top surface 161 and the bottom surface 162 of the first nitride semiconductor layer 120, etching of the barrier layer 126 and the channel layer 124 in the vicinity of the third nitride semiconductor layer 142D can be readily prevented. For example, when a dent similar to the dent 165 of the second nitride semiconductor layer 142S forms in the third nitride semiconductor layer 142D, etching of the formed dent hardly affects the cap layer 128 and the barrier layer 126 in the vicinity of the third nitride semiconductor layer 142D. The first distance L0 does not necessarily need to be constant in the nitride semiconductor device 100, for example, in accordance with the formation of the first recess 140S and the second recess 140D. When the first distance L0 is not constant, the values of the distance L3 and the distance L4 can be compared with the maximum value of the first distance L0. In the formation of the second nitride semiconductor layer 142S and the third nitride semiconductor layer 142D, the distance L3 and the distance L4 do not necessarily need to be constant in the nitride semiconductor device 100. When at least one of the distance L3 or the distance L4 is not constant, the value of the first distance L0 can be compared with the minimum value of the distance L3 and the distance L4.

The distance L1 between the top surface 161 and the top surface 163 is, for example, 5 nm or more and 30 nm or less. When the distance L1 is 5 nm or more, etching of the barrier layer 126 and the channel layer 124 in the vicinity of the second nitride semiconductor layer 142S can be readily prevented. Also, when the distance L1 is 30 nm or less, formation of an excessive step due to the first covering portion 144S can be readily prevented. The distance L1 may be 7 nm or more and 28 nm or less, or may be 10 nm or more and 25 nm or less.

The distance L2 between the top surface 161 and the top surface 164 is, for example, 5 nm or more and 30 nm or less. When the distance L2 is 5 nm or more, etching of the barrier layer 126 and the channel layer 124 in the vicinity of the third nitride semiconductor layer 142D can be readily prevented. Also, when the distance L2 is 30 nm or less, formation of an excessive step due to the second covering portion 144D can be readily prevented. The distance L2 may be 7 nm or more and 28 nm or less, or may be 10 nm or more and 25 nm or less.

The top surface of the first covering portion 144S and the top surface of the second covering portion 144D do not necessarily need to be flat. The top surface of the first covering portion 144S may be inclined to follow the side wall of the first recess 140S, and the top surface of the second covering portion 144D may be inclined to follow the side wall of the second recess 140D. Also, the top surface 163 of the second nitride semiconductor layer 142S including the first covering portion 144S may be flat, and the top surface 164 of the third nitride semiconductor layer 142D including the second covering portion 144D may be flat.

When the first nitride semiconductor layer 120 includes the cap layer 128 including the top surface 161, it is possible to reduce a gate leakage current and improve long-term reliability.

A length W1 of the first covering portion 144S in the X-axis direction is, for example, 30 nm or more and 200 nm or less. When the length W1 is 30 nm or more, etching of the barrier layer 126 and the channel layer 124 in the vicinity of the second nitride semiconductor layer 142S can be readily prevented. Also, when the length W1 is 200 nm or less, a short circuit between the gate electrode 50 and the second nitride semiconductor layer 142S can be readily prevented. The length W1 may be 40 nm or more and 150 nm or less, or may be 50 nm or more and 100 nm or less.

A length W2 of the second covering portion 144D in the X-axis direction is, for example, 30 nm or more and 200 nm or less. When the length W2 is 30 nm or more, etching of the barrier layer 126 and the channel layer 124 in the vicinity of the third nitride semiconductor layer 142D can be readily prevented. Also, when the length W2 is 200 nm or less, a short circuit between the gate electrode 50 and the third nitride semiconductor layer 142D can be readily prevented. The length W2 may be 40 nm or more and 150 nm or less, or may be 50 nm or more and 150 nm or less. The length W1 and the length W2 may be equal to or different from each other.

When the electrical resistance of the second nitride semiconductor layer 142S and the electrical resistance of the third nitride semiconductor layer 142D are lower than the electrical resistance of the channel region 155, the electrical resistance between the source electrode 44S and the drain electrode 44D can be lowered.

When the second nitride semiconductor layer 142S and the third nitride semiconductor layer 142D contain n-type impurities, a low electrical resistance can be readily achieved in the second nitride semiconductor layer 142S and the third nitride semiconductor layer 142D. The n-type impurities are not limited to Ge, and may be silicon (Si). The concentration of the n-type impurities is, for example, 1×10²⁰ cm⁻³ or more. When the concentration of the n-type impurities is 1×10²⁰ cm-3 or more, an especially low electrical resistance can be readily achieved in the second nitride semiconductor layer 142S and the third nitride semiconductor layer 142D. The concentration of the n-type impurities may be 5×10²⁰ cm⁻³ or more, or may be 1×10²¹ cm⁻³ or more. The second nitride semiconductor layer 142S and the third nitride semiconductor layer 142D having a concentration of the n-type impurities of 1×10²⁰ cm⁻³ or more can be formed, for example, through sputtering, but are difficult to form through MOCVD. The concentration of the n-type impurities can be measured through secondary ion mass spectrometry.

When the second nitride semiconductor layer 142S is provided in the first recess 140S and the third nitride semiconductor layer 142D is provided in the second recess 140D, the second nitride semiconductor layer 142S and the third nitride semiconductor layer 142D can be readily formed.

When the insulating layer 130 is provided over the top surface 161 and contacts the first covering portion 144S and the second covering portion 144D, the first nitride semiconductor layer 120 can be protected by the insulating layer 130.

Also, in the first production method, the sizes of the first covering portion 144S and the second covering portion 144D can be adjusted upon etching of the insulating layer 130 (see FIG. 5). In the second production method, the sizes of the first covering portion 144S and the second covering portion 144D can be adjusted upon ashing of the mask (see FIG. 12).

According to the present disclosure, a high breakdown voltage can be achieved.

Although the embodiments have been described above in detail, the present disclosure is not limited to the specific embodiments, and various alterations and modifications are possible within the scope of claims recited.

What is claimed is:

1. A nitride semiconductor device, comprising:
a first nitride semiconductor layer including a channel layer and a barrier layer stacked along a first axis, the first nitride semiconductor layer including a first surface perpendicular to the first axis; and
a second nitride semiconductor layer and a third nitride semiconductor layer sandwiching the channel layer and the barrier layer between the second nitride semiconductor layer and the third nitride semiconductor layer along a second axis perpendicular to the first axis, wherein
in a cross-sectional view including the first axis and the second axis, the second nitride semiconductor layer includes a first covering portion covering a first portion of the first surface, and the third nitride semiconductor layer includes a second covering portion covering a second portion of the first surface.

2. The nitride semiconductor device according to claim 1, wherein
the first nitride semiconductor layer includes a second surface opposite to the first surface,
the second nitride semiconductor layer includes a third surface having a distance from the second surface, the distance being greater than a first distance between the first surface and the second surface, and
the third nitride semiconductor layer includes a fourth surface having a distance from the second surface, the distance being greater than the first distance.

3. The nitride semiconductor device according to claim 2, wherein
a distance between the first surface and the third surface is 5 nm or more and 30 nm or less, and
a distance between the first surface and the fourth surface is 5 nm or more and 30 nm or less.

4. The nitride semiconductor device according to claim 1, wherein
the first nitride semiconductor layer includes a cap layer including the first surface.

5. The nitride semiconductor device according to claim 1, wherein
a length of the first covering portion in a direction along the second axis is 30 nm or more and 200 nm or less, and
a length of the second covering portion in the direction along the second axis is 30 nm or more and 200 nm or less.

6. The nitride semiconductor device according to claim 1, wherein
the channel layer includes a channel region containing a two dimensional electron gas, and
an electrical resistance of the second nitride semiconductor layer and an electrical resistance of the third nitride semiconductor layer are lower than an electrical resistance of the channel region.

7. The nitride semiconductor device according to claim 1, wherein
the second nitride semiconductor layer and the third nitride semiconductor layer contain n-type impurities.

8. The nitride semiconductor device according to claim 7, wherein
a concentration of the n-type impurities is 1×10²⁰ cm⁻³ or more.

9. The nitride semiconductor device according to claim 1, wherein
the first nitride semiconductor layer includes a first recess and a second recess sandwiching the channel layer and the barrier layer between the first recess and the second recess along the second axis,
the second nitride semiconductor layer is provided in the first recess, and
the third nitride semiconductor layer is provided in the second recess.

10. The nitride semiconductor device according to claim 1, further comprising:
an insulating layer provided over the first surface and in contact with the first covering portion and the second covering portion.

11. A production method of a nitride semiconductor device, the production method comprising:
providing a first nitride semiconductor layer including a channel layer and a barrier layer stacked along a first axis, the first nitride semiconductor layer including a first surface perpendicular to the first axis; and
forming a second nitride semiconductor layer and a third nitride semiconductor layer through sputtering, the second nitride semiconductor layer and the third nitride semiconductor layer sandwiching the channel layer and the barrier layer between the second nitride semiconductor layer and the third nitride semiconductor layer along a second axis perpendicular to the first axis, wherein
in a cross-sectional view including the first axis and the second axis, the second nitride semiconductor layer includes a first covering portion covering a first portion of the first surface, and the third nitride semiconductor layer includes a second covering portion covering a second portion of the first surface.

12. The production method of the nitride semiconductor device according to claim 11, wherein
the production method of the nitride semiconductor device includes, between the provision of the first nitride semiconductor layer and the formation of both the second nitride semiconductor layer and the third nitride semiconductor layer, forming a first recess and a second recess in the first nitride semiconductor layer, the first recess and the second recess sandwiching the channel layer and the barrier layer between the first recess and the second recess along the second axis,
the second nitride semiconductor layer is formed in the first recess, and
the third nitride semiconductor layer is formed in the second recess.

13. The production method of the nitride semiconductor device according to claim 12, wherein
the production method of the nitride semiconductor device includes, between the provision of the first nitride semiconductor layer and the formation of both the first recess and the second recess:
forming an insulating layer over the first surface;
forming a mask over the insulating layer, the mask including a first opening and a second opening; and
etching the insulating layer through the first opening and the second opening to form a third opening and a fourth opening in the insulating layer, the third opening being continuous with the first opening and larger than the first opening in a plan view and the fourth opening being continuous with the second opening and larger than the second opening in the plan view, and
the first recess and the second recess are formed by etching through the first opening and the second opening, and
the production method of the nitride semiconductor device includes
removing the mask between the formation of both the first recess and the second recess and the formation of both the second nitride semiconductor layer and the third nitride semiconductor layer.

14. The production method of the nitride semiconductor device according to claim 12, wherein
the production method of the nitride semiconductor device includes, between the provision of the first nitride semiconductor layer and the formation of both the first recess and the second recess:
forming an insulating layer over the first surface;
forming a mask over the insulating layer, the mask including a first opening and a second opening; and
etching the insulating layer through the first opening and the second opening to form a fifth opening and a sixth opening in the insulating layer, the fifth opening being continuous with the first opening and the sixth opening being continuous with the second opening, and
the first recess and the second recess are formed by etching through the first opening and the second opening, and
the production method of the nitride semiconductor device includes, between the formation of both the first recess and the second recess and the formation of both the second nitride semiconductor layer and the third nitride semiconductor layer:
ashing the mask to widen the first opening and the second opening and expose a first portion of the insulating layer from the first opening and a second portion of the insulating layer from the second opening;
removing the first portion of the insulating layer exposed from the first opening and the second portion of the insulating layer exposed from the second opening; and
removing the mask after the removal of the first portion of the insulating layer exposed from the first opening and the second portion of the insulating layer exposed from the second opening.
